(19) United States
(12) Patent Application Publication
(10) Pub. No.: US 2025/0151459 A1
(43) Pub. Date: May 8, 2025

(54) METHOD OF PROCESSING AN OPTOELECTRONIC DEVICE AND OPTOELECTRONIC DEVICE

(71) Applicant: ams-OSRAM International GmbH, Regensburg (DE)

(72) Inventors: Lutz Hoeppel, Alteglofsheim (DE); Christian Schliebe, Grossmehring (DE); Markus Heyne, Regensburg (DE)

(21) Appl. No.: 18/727,934

(22) PCT Filed: Jan. 14, 2022
(86) PCT No.: PCT/EP2022/050808

§ 371 Date: Jul. 10, 2024

(51) Int. Cl. H10H 20/01; H10H 20/825; H10H 20/833; H10H 20/84

(52) U.S. Cl. CPC H10H 20/016; H10H 20/0137; H10H 20/034; H10H 20/0362; H10H 20/825; H10H 20/833; H10H 20/84

(57) ABSTRACT

Embodiments provide a method for processing an optoelectronic device, wherein the method includes providing a functional semiconductor layer stack with a conductive layer and hard mask layer located on the conductive layer. Both hard mask and conductive layer are structured, and a protective layer is arranged on sidewalls of the conductive layer. Then two dry etching and a wet etching process are performed to obtain an optoelectronic device. Portions of the hard mask layer on the conductive layer remain on the functional layer stack and form an integral part of the device.

### CROSS-REFERENCE TO RELATED APPLICATIONS

This patent application is a national phase filing under section 371 of PCT/EP2022/050808, filed Jan. 14, 2022, which is incorporated herein by reference in its entirety.

### TECHNICAL FIELD

The present invention concerns a method for processing an optoelectronic device and an optoelectronic device.

### BACKGROUND

Optoelectronic devices with a diameter of its emitting surface of less than 70 μm and down to 1 μm are referred to as μ-LEDs. Such μ-LEDs have an emitting area of about 1 μm² to about 100 μm² and are configured to emit blue, red, and green light. The processing of such LEDs in a very small regime comprises various challenges. Some of those are related to the treatment of damaged side edges in particular of the active regions in order to stabilize and optimize the electro-optical performance of extremely small μ-LEDs. For this purpose, one has proposed using wet chemical etching processes to treat the dry-chemical side edges of the semiconductor layers, particularly in the area of the pn junction.

Another challenge is given by the arrangement of the p-side mirror on the fictional semiconductor stack to achieve a reasonably good performance. For this purpose, the mirror should cover most if not all of the p-side. In conventional techniques, the mirror stack, mostly containing Ag is structured using a lift-off technique. However, such a process requires several lithographic steps leading to potential misalignment. In addition, the conventional approach often causes inclined sidewalls of the mirror reducing the overall performance.

### SUMMARY

Embodiments improve the situation by reducing the lithographic steps without compromising the quality or the performance of the device.

With regard to structure size and shape of the μ-LEDs, the inventors propose to use only a single photolithographic step to structure the hard mask resulting in a self-alignment with the underlying conductive layer. The hard mask also forms the protection during dry-etching and wet-etching processes. This approach enables a wet etching process by KOH only for the relevant vertically confined part of the mesa around the pn-junction.

In the process flow, the inventors propose to structure hard mask and conductive layer on the surface of a functional layer stack together in a single step resulting in an alignment of the sidewalls of the conductive layer and the hard mask stack.

In an aspect a method of processing an optoelectronic device comprises the step of providing a functional semiconductor layer stack. The functional semiconductor layer stack includes an active region that is buried beneath a surface of the functional semiconductor layer stack. A conductive layer is arranged on the surface of the layer stack. In this regard the conductive layer may comprise various properties and/or functionalities, including but not limited to providing a current distribution into a top layer of the functional layer stack. The conductive layer may comprise a transparent and/or a highly reflective metal.

Then, a patterned hard mask stack is deposited on the conductive layer, wherein the hard mask stack comprises at least a first mask layer. The patterned hard mask stack and the conductive layer are dry etched together, wherein the patterned hard mask serves as alignment for the conductive layer to provide a structured hard mask stack and expose portions of the functional semiconductor layer stack. In a subsequent step a first protective layer is deposited at least on the sidewall of the conductive layer, the first protective layer comprising similar etching properties as the first layer and being resilient to a wet etching process. In other words, the first layer of the structured hard mask stack may be encapsulated by the material of the first protective layer.

In a subsequent step, a first anisotropic dry chemical etching process is performed, etching portions of the structured hard mask stack and the functional semiconductor layer stack not covered by the structured hard mask stack down to a first depth exposing edges of the active region. One may use a chlorine containing gas for this first dry etching process. Due to the anisotropic etching the first protective layer on the sidewall (both of the conductive layer and the hard mask stack) is not etched but still protects the sidewalls.

A wet chemical etching process is performed in a following step in particular to treat and shape the surfaces of the exposed functional semiconductor stack. During this wet etching process, the first protective layer protects the sidewalls of the conductive layer from being etched. Once the wet etching process to remove damages from the mesa sidewalls and particularly from the edges of the active region is finished, the exposed edges of the active region are covered with a second protective layer.

Then, a second anisotropic dry chemical etching is performed removing portions of the hard mask stack and portions of the functional semiconductor layer stack not covered by the structured hard mask and the third material to a second depth. However, a small amount of the hard mask stack, particularly of the material of the first hard mask layer remains on the surface of the conductive layer and will form an integral part of the optoelectronic device.

Finally, the second protective layer is removed, thereby exposing the first protective layer and again the sidewall edges of the active region. The optoelectronic device is then further processed, such that a portion of the first mask layer (31) and the second protective layer remains on the functional layer stack and on the sidewall of the conductive layer, respectively

The method according to the proposed principle combines the possibility of a self-alignment of a hard mask with the material of the underlying conductive material. This avoids the necessity for separate lithographic steps to pattern and structure the conductive layer and the hard mask. The structured mask layer stack acts as a mask layer for the various dry and wet etching processes forming the mesa structure.

In some aspects, the step of providing a functional semiconductor comprises depositing a functional layer stack and a conductive material on the surface of the functional layer stack. Optionally, an annealing layer can be deposited that is subsequently removed. In some instances, the annealing layer comprises ZnO. A conductive layer is deposited on the conductive material, particularly after removing the annealing layer on the conductive material, with the conductive layer being more compatible with the dry etching process used to structure the patterned hard mask or being more resilient against KOH.

In some other aspects, the step of depositing a patterned hard mask stack comprises the steps of depositing the first mask layer of SiNx on the conductive layer having a thickness in the range of larger than 500 nm and in particular between 700 nm and 1500 nm and in particular between 1000 nm and 1300 nm. A second layer is optionally deposited comprising SiO2 on the first mask layer, the second layer having a smaller thickness than the first mask layer. Finally, a photoresist is applied and patterned.

The first protective layer comprises the same material as the first layer having a thickness on the sidewalls in the range of 10 nm to 70 nm and in particular between 20 nm to 40 nm. In some aspects, the first protective layer encapsulates the first mask layer of the structured hard mask stack and at least partially covers the exposed portions of the functional semiconductor layer stack.

The first anisotropic dry etching process may cause inclined sidewalls in the functional layer stack exposing edges of the active region. The depth of the etching process can be controlled and may range between 300 nm and 1000 nm and in particular between 400 nm and 600 nm.

In another aspect, the wet chemical etching process comprises etching with KOH. After the wet etching process is finished, the exposed and treated edges and sidewalls of the active region are covered by a thin second protective layer. Said second protective layer may comprise Al2O3. It is deposited in some instance by an atomic layer deposition process like ALD or also CVD with a thickness smaller than 60 nm and particularly than 40 nm. The second protective layer protects the sidewalls and the edges of the active region from the subsequent dry etching process without damaging or interfering with the edges of the active region itself.

In some instances, the step of second anisotropic dry chemical etching is a repetition of the first dry etching process using the same etchant. Alternatively, a different etchant or different process parameter can be used to control the etch process. The second anisotropic dry chemical etching may remove the structured hard mask stack and the first mask layer down to a small residual layer, which will remain on the surface of the conductive layer. The second anisotropic dry chemical etching removes the second protective layer on top of the functional semiconductor stack and etches the functional semiconductor stack down to a second depth.

In some further instances, the step of second anisotropic dry chemical etching causes inclined surface portions of the functional layer stack not covered by the second protective layer. The inclination is different than the one on the sidewalls being treated by the wet etch process. In some aspects, second anisotropic dry chemical etching is performed until an undoped buffer layer of the functional layer stack is reached.

Finally, the residual of the second protective layer is removed, for example using an acid, in which the second protective layer is soluble This process will again expose the first mask layer on top of the conductive layer and on the sidewalls of the conductive layer.

The present method can be applied to the processing of μ-LEDs based on various material systems including semiconductor materials like GaN, InGaN and InAlGaN. These material systems do comprise a crystal orientation that is substantially inert to the wet chemical etching process for removing the hard mask.

The optoelectronic device can then be further processed to finalize the device. In some aspects, a third protective layer is deposited on the sidewalls and the surface encapsulating remaining portions of the first mask layer, the conductive layer, and the active region of the functional semiconductor layer stack. The third protective layer can comprise Al2O3 and is deposited by an ALD process. The thickness of the third protective layer ranges from 10 nm to about 100 nm and in particular form 35 nm to 65 nm. The third protective layer and the remaining portion of the first mask layer is then structured to expose a portion of the conductive layer. A metal layer is filled into the recess also covering the surface of the third protective layer. The metal layer forms the contact for the p-side of the optoelectronic device.

For processing the n-side, the optoelectronic device can be encapsulated with a sacrificial layer. The sacrificial layer comprises SiO2 and has a thickness in the range of about 100 nm to 300 nm. An anchor is formed supporting the optoelectronic device, the anchor extending through the sacrificial layer, where the sacrificial layer comprises a recess. The device is then casted with a filling material, the filling material also filling the recess thereby forming the anchor. The filling material can partly be removed to gain access to the sacrificial layer and the n-side surface of the optoelectronic device. After applying a metal contact to the n-side surface of the device, the sacrificial layer can be removed. The device now rests on the anchor.

Some other aspects relate to an optoelectronic device comprising a functional layer stack. The functional layer stack includes a first doped layer, a second doped layer and an active region located between the first doped layer and the second doped layer. A conductive layer is arranged on the surface of the second doped layer. The layer stack further includes a structured non-conductive mask layer on the conductive layer and a structured protective layer on the non-conductive mask layer. A metal layer covers the structured protective layer connecting electrically the conductive layer. In accordance with the proposed principle, the structured protective layer extends on the sidewalls of the structured non-conductive mask layer, of the conductive layer and of the active region. In other words, the structured protective layer covers the sidewalls of the structured non-conductive mask layer, the conductive layer, and the active region. Furthermore, the sidewall of the non-conductive mask layer is aligned with the sidewall of the conductive layer. There is no step or lateral displacement between the sidewalls.

The optoelectronic device according to the proposed principle deliberately uses material from the hard masks used to align the structure of the conductive layer and the mesa structure. It forms an integral part of the device. This is different to conventional approaches, in which the hard mask is usually removed before processing the device further. In some instances, the sidewall of the active region is also aligned with the sidewall of the conductive layer. In this regard the expression “aligned” means substantially in a straight line, that is without a step and the like. The sidewall of the conductive layer may be covered with a material, having similar or the same properties as the non-conductive mask layer. In such case, the sidewall of the active region is straight with said material and the material is substantially straight as well. The above-mentioned alignment is also referred to as “flush.”

In some instances, a second sidewall forming a part of the first doped layer is laterally displaced to the sidewall of the active region and extends along a portion of the first doped layer. It may also be inclined with regards to the sidewall of the active region. More particular, in some instances an angle between the sidewall of the active region and the second sidewall is larger than 0° and in particular between 1° and 5°.

In some further aspects, the material of the structured and non-conductive mask layer may include SiNx. Likewise, the material covering the sidewalls of the conductive layer also comprises SiNx. The conductive layer comprises in some instances a layer stack, with one layer being a metal layer, in particular an Ag layer. A second layer may include a transparent conductive oxide, in particular ITO, which also has some properties useful during the manufacturing process.

The metal layer is located only on the top surface of the structured protective layer. The protective layer may comprise one or more recesses, such that the metal filling the recesses extends through the non-conductive mask layer to the conductive layer. The structured protective layer can comprise Al2O3.

### BRIEF DESCRIPTION OF THE DRAWINGS

Further aspects and embodiments in accordance with the proposed principle will become apparent in relation to the various embodiments and examples described in detail in connection with the accompanying drawings in which

FIGS. 1A to 1D show the first steps of a method of processing an optoelectronic device in accordance with some aspects of the proposed principle;

FIGS. 2A to 2C illustrate further steps of a method of processing an optoelectronic device in accordance with some aspects of the proposed principle;

FIGS. 3A and 3B show some further steps of a method of processing an optoelectronic device in accordance with some aspects of the proposed principle;

FIG. 4 illustrates an alternative embodiment of a method of processing an optoelectronic device in accordance with some aspects of the proposed principle; and

FIGS. 5A to 5H illustrate some further steps of a method of processing an optoelectronic device in accordance with some aspects of the proposed principle.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

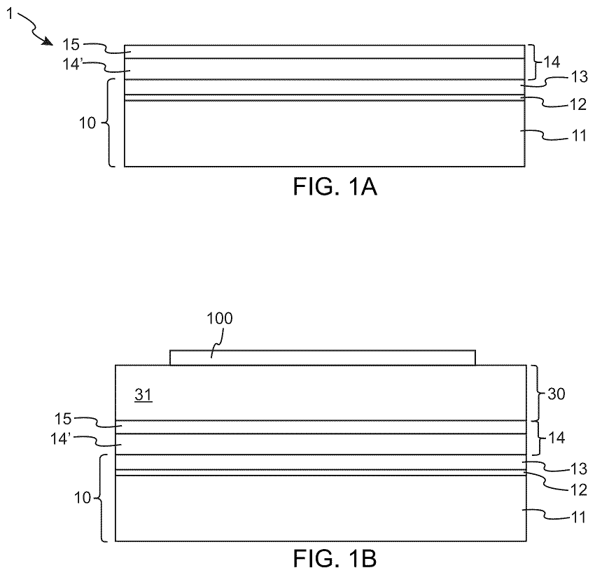

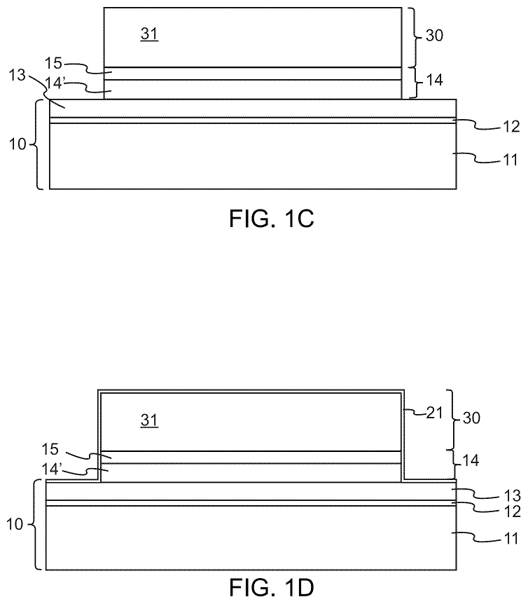

FIG. 1A to 1D illustrate the first steps of a method for processing an optoelectronic device in accordance with some aspects of the proposed principle. The optoelectronic device also referred to as a μ-LED is configured to emit light of certain wavelengths, the wavelength itself depending on the base material used. The optoelectronic device 1 comprises a functional semiconductor layer stack 10 including several differently doped layers and an active region 12. The functional semiconductor layer stack is deposited on a growth substrate not shown in this figure including one or more layer structures to prepare the deposition of the various layers of the layer stack 10.

More particularly, the functional semiconductor layer stack 10 comprises a first doped layer 11 in particular an n-doped layer directly deposited on the buffer layer structure or the growth substrate (not shown here), respectively. The n-doped first layer 11 may include a current distribution layer, a sacrificial layer or any other suitable layers providing current injection into an active region 12 deposited on the first doped layer 11. Active region 12 includes a quantum well structure or a multi-quantum well structure with a bandgap that is suitable to emit light of the desired wavelength.

Active region 12 may include quantum well intermixed areas in portions close to a Mesa structure processed in subsequent steps of the proposed method. On top of active region 12, a second doped layer in particular a p-doped layer 13 is provided. In this regard, the second doped layer 13 as well as the first doped layer 11 may contain a constant doping profile or variable doping profile to ensure proper current injection into the active region 12 and achieve the desired electric characteristics.

A conductive layer 14 is provided on top surface of second doped layer 13. Conductive layer 14 comprises metal mirror structure 14′ and contains a metal alloy including Ag and Zn for example. The metal layer 14′ is deposited as illustrated in FIG. 1A covering the entire top surface of second layer 13. Its thickness may be in the range of 100 nm to 150 nm. Then, ZnO or another small layer in the range of about 50 nm is deposited on the Ag layer and an annealing process performed. To ensure that top layer also has some etch stopping properties, the ZnO layer may subsequently be replaced by the illustrated ITO layer 15. Both layers 14′ and 15 form conductive layer 14. Conductive layer 14 is utilized as a contact layer as well as the reflective layer for light being generated in the active region 12.

After depositing the various layers of the functional semiconductor layer stack 10 including the conductive layer 14, a hard mask layer 31 is deposited on the surface of the conductive layer. Hard mask layer contains SiNx and is about 1000 nm thick. The thickness is chosen such that after the various dry and wet chemical etching steps, a smaller thickness layer of about 70 nm to 150 nm or more particular about 100 nm of hard mask layer 31 remains on the surface of conductive layer 14 and forms an integral part of the optoelectronic device. The silicon nitride layer 31 acts as a protective layer for the conductive layer 14 during the wet etching process utilizing KOH. However, it is etched by a chlorine dry etching process and therefore requires the above-mentioned higher thickness.

FIG. 1B illustrates the result of the deposition of a hard mask layer 31 applied to the surface of conductive layer 14. In a subsequent step, a photoresist layer 100 is applied on top of the hard mask layer and patterned to expose surface portions of layer 31.

After patterning the hard mask and layer 31, a first etching process, i.e. a dry etching process is performed illustrated in FIG. 1C. The etching process removes the hard mask layer 31 and also the conductive layer 14. In the present example, the etching process removes the ITO layer 15, the AG layer 14′ down to the surface of the functional semiconductor layer stack. During the etching process, the sidewall of the mask layer 31 is aligned with the sidewall of conductive layer 14. This alignment is substantially preserved in subsequent steps and can be observed in the final optoelectronic device.

The etchant used for the dry etching process may contain Cl in combination with an oxygen reducing agent so to avoid that the exposed sidewall of the Ag layer 14′ is oxidized. In another example, the dry chemical etching process may use CF3, CF4 or CxHyFz compound or SF6 together with an inert gas (e.g. Argon). The dry etching process may be anisotropic to avoid an under etch of the conductive layer 14 below the hard mask layer 31.

In the next step depicted in FIG. 1D a first protective layer 21 is deposited on the top surface of the mask layer 31, its sidewalls including the sidewalls of the conductive layer 14 and the exposed surface of the functional semiconductor stack. The material of the first protective layer 21 is SiNx, the same material as used for the hard mask layer. As stated before, SiNx is resilient against etching with KOH and will protect the conductive layer from being etched in a subsequent step. The thickness of protective layer 21 is in the range of a few 10 nm, for example in the range between 20 nm and 70 nm and in particular about 25 nm and 45 nm. As part of the hard mask layer 31, the material covering the sidewalls of conductive layer 14 will remain on the sidewalls and become integral part of the optoelectronic device.

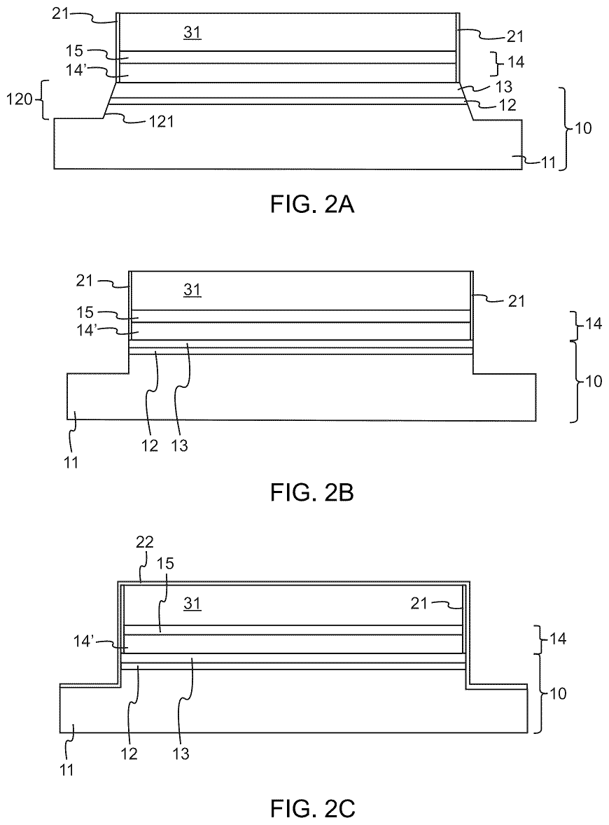

FIGS. 2A to 2C illustrate the next steps of the method of processing an optoelectronic device in accordance with the proposed principle.

A first anisotropic dry etching process to obtain a shallow mesa structure is performed and its result illustrated in FIG. 2A. The anisotropic dry etching process comprises a chlorine gas and will remove portions of mask layer 31, the protective layer 21 on the surface of the semiconductor stack and expose portions the semiconductor stack 10. Material of the functional semiconductor stack 10 including layers 13, the active region 12 and a portion of the first layer 11 is etched to obtain a shallow mesa structure 120. The sidewalls 121 of the shallow mesa structure are slightly inclined due to the shadowing effects of the anisotropic dry etching process. The material of the protective layer 21 applied on the sidewalls of hard mask layer 31 and on the sidewalls of conductive layer 14 remains.

As a result of this first anisotropic dry etching process, side edges of active region 12 are exposed. The nature of the dry etching causes some damage to the crystal structure on the side edge of active region 12 as well as of region 13 and 11, leaving them with a high density of non-radiative recombination centers. To remove most of these non-radiative recombination centers, a wet etching process using KOH is performed. The wet etching process will expose well defined crystal facets preferable those that lead to substantially vertical sidewalls 121, so that they are aligned with the sidewall of the hard mask layer 31 and the sidewalls of the conductive layer 14. KOH is an etchant that does not significantly etch SiNx. Consequently, the material of the first protective layer 21 on the sidewall covering the conductive layer 14 is not etched and the conductive layer is protected. Likewise mask layer 31 acts as a protective layer for layer 14 beneath during the wet etching process. The resulting structure is illustrated in FIG. 2B.

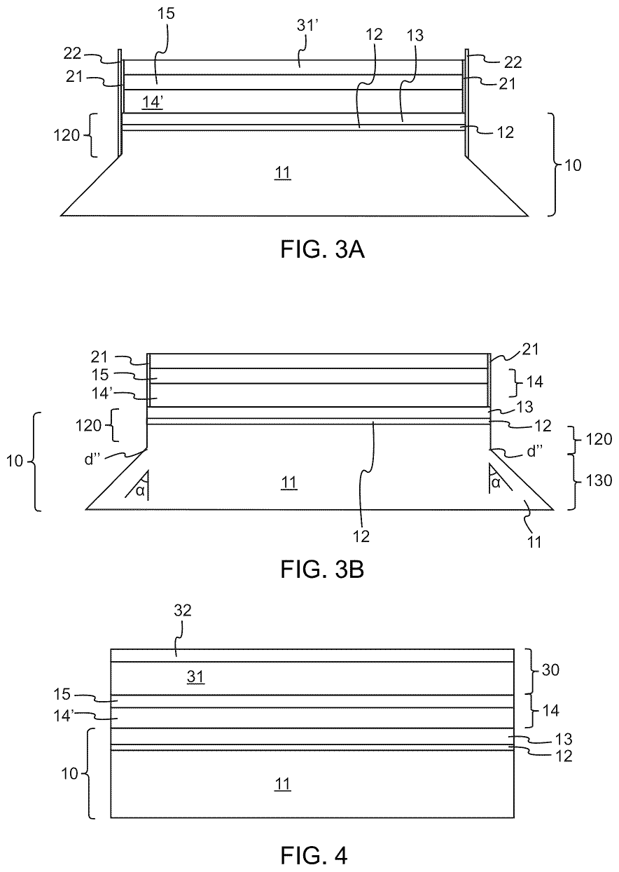

The exposed edges of the active region 12 as well as the first protective layer 21 on the side walls and the hard mask layer 31 are subsequently covered by a second protective layer 22 after the wet etching process is finished. The second protective layer 22 comprises Al2O3 and is deposited using an ALD process. The thickness is in the range of a few nanometers to 60 nm. The second protective layer 22 also extends on the top surface of the functional semiconductor stack previously etched. Layer 22 protects the active region 12 against the subsequent anisotropic dry etching process which is used to etch a deep mesa structure as illustrated in FIG. 3A.

The second anisotropic dry etching process depicted in FIG. 3A removes further portions of mask layer 31 down to a small layer 31′. For this purpose, the thickness of mask layer 31 is adjusted to the etch rate of the first and second anisotropic processes ensuring that some material of mask layer 31 remains on the surface. In addition, the material of second protective layer 22 on the top surface of the functional layer stack 10 is removed and the functional layer stack etched until the undoped buffer layer is reached. As a result, inclined sidewalls are generated in the first doped layer 11 of the functional layer stack. The inclination of the sidewalls depends on the etchant as well as the process parameters thereof and is in the range of a few degrees. Due to the anisotropic etching process, the second protective layer 22 material on the sidewall will substantially remain intact protecting the surfaces of the functional layer stack in area 120 exposed during the first dry etching process.

After the second anisotropic dry etching process, the second protective layer 22 is removed in FIG. 3B using a solution of H3PO4. The removal process results in a small lateral displacement in the first doped layer, whose width d″ corresponds substantially to the thickness of the Al2O3 protective layer. The SiNx layer on the sidewalls of the conductive layer 14 remains. Area 130 comprises the inclined sidewalls surfaces with an angle α in the range of a few degrees.

With the proposed method an optoelectronic device can be processed with a deep Mesa structure without changing the pattern mask during the overall process. In particular, the proposed structured hard mask on the surface aligns with the conductive layer. The first protective layer provides enough protection against the dry chemical etching process, respectively while at the same time enabling a very precise and selective etching process. Apart from the single hard mask structure 30, an alternative way of processing an optoelectronic device is illustrated in FIG. 4.

This optoelectronic device comprises a functional layer stack 10 like the embodiment of the previously proposed method being covered by the conductive layer 14 on its surface. In contrast to the previous embodiment, hard mask structure layer 30 includes a first layer 31 made of SiNx, and a SiO2 layer 32 covering the SiNx layer. The SiO2 layer 32 is relatively thin but its etch rate during the first anisotropic etching process is smaller than that of the SiNx material, such that less SiNx material is needed. Hence, like the SiNx material, the SiO2 layer is substantially removed during the first dry etching process, but at a smaller etch rate.

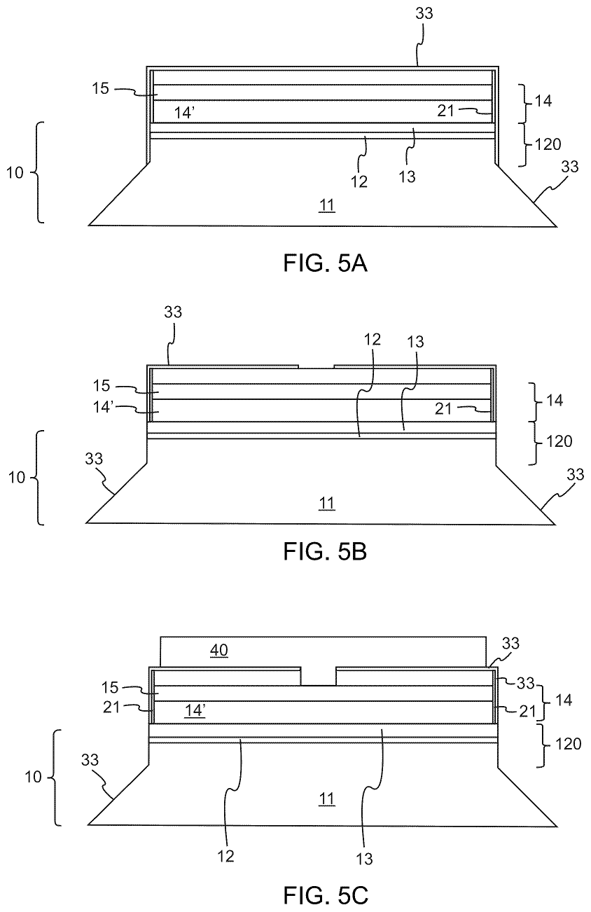

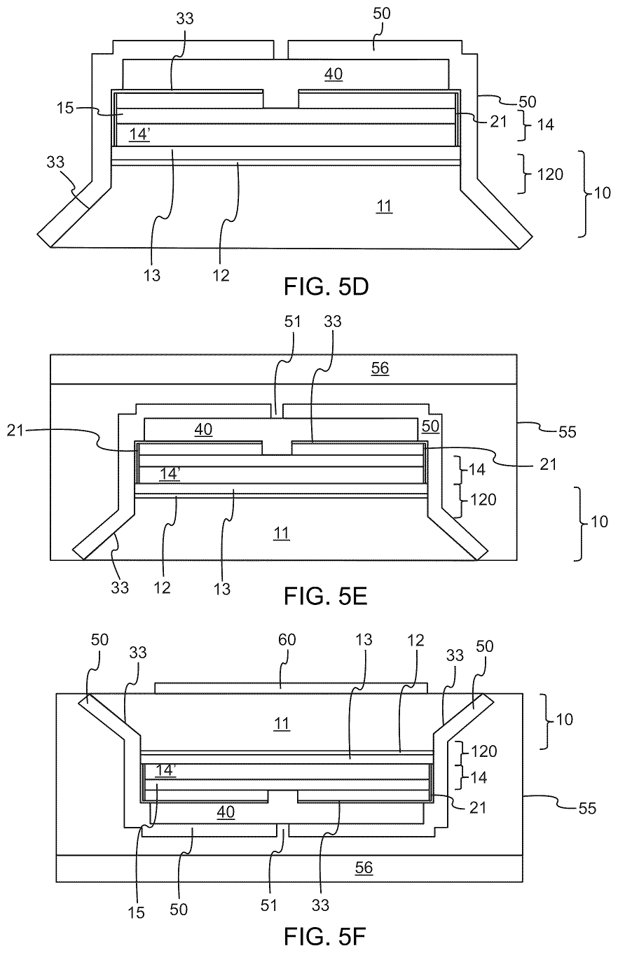

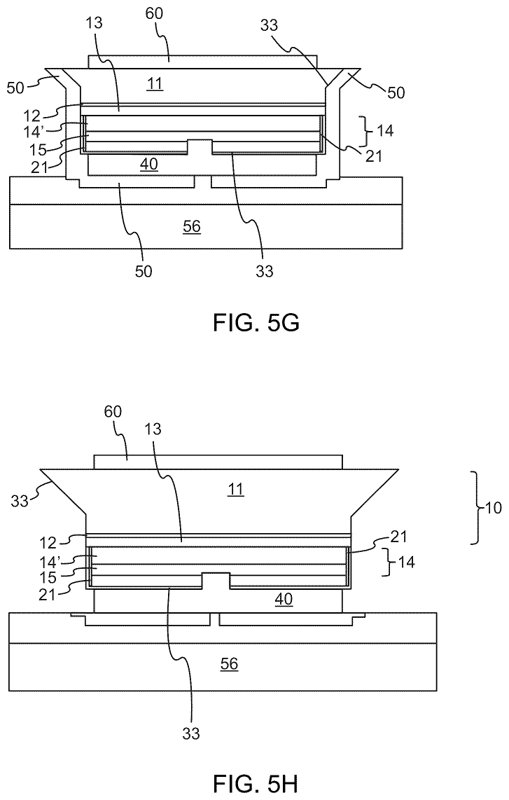

FIG. 5A to 5H illustrate the next few steps of processing the device further.

The layer of SiNx on the sidewalls is left intact as shown in FIG. 5A, because a third protective layer 33 is deposited covering the surfaces of the device. In some examples, ozone may be used for the deposition process, so it is preferable that SiNx remains and covers the sidewall of the conductive layer to avoid its oxidation. The thickness of the third protective layer 33 lies in the range of about 40 nm to 100 nm. The resulting structure is then processed further as shown in FIG. 5B. The protective layer 33 is covered by a photoresist layer, which is patterned. The third protective layer 33 is structured, such that a recess is formed in layer 33 and hard mask layer 31, respectively to expose a part of the conductive layer 14.

The recess as well as the top surface of the Al2O3 layer 33 is subsequently covered with a metal layer 40 forming the contact for the optoelectronic device, see FIG. 5C. The metal extends into the recess and electrically contacts the conductive layer 14. Then, as shown in FIG. 5D, a sacrificial layer 50 is arranged on the optoelectronic device covering the overall surface. The sacrificial layer may comprise SiO2 or another material suitable to be removed later on. The sacrificial layer 50 is patterned to open a small recess, providing access to the metal layer. As it will become apparent later on, the recess can comprise different shape and also be arranged at various positions on the device. It will subsequently form a support structure for supporting and holding the optoelectronic device in place. In the present example the recess is formed on the top surface above the recess through the SiNx layer 31.

In a subsequent step, the device is encapsulated in a carrier material 55. The carrier material 55 comprises a polymer or plastic material. The carrier material 55 also fills the recess in the sacrificial layer forming an anchor element 51. An additional support carrier 56 is arranged on the carrier material 55 as shown in FIG. 5E. The additional support carrier 56 allows for rebonding and removing the growth substrate.

FIG. 5F illustrate the next steps. First, the device is turned to gain access to the n-doped side. If necessary, the surface is grinded or otherwise smoothened and partly removed to get access to the n-side of the functional semiconductor stack. A transparent metal n-contact 60 e.g. ITO is deposited on top of the n-side surface of layer 11 and patterned using a photo resist (not shown). The encapsulating material 55 can be partially removed to get easier access to the sacrificial layer 50 illustrated in FIG. 5G. As shown, the recess in the sacrificial layer 50 is now filled with the encapsulating material 55 thus supporting the optoelectronic device. In the last step shown in FIG. 5H, a release etch is performed to remove the sacrificial layer 50 from the side and beneath the device. The optoelectronic device now rests only on the support structure.

1.-24. (canceled)

25. A method for processing an optoelectronic device, the method comprising:
providing a functional semiconductor layer stack comprising an active region spaced apart from a surface of the functional semiconductor layer stack, the surface comprising a conductive layer deposited thereon;
depositing a patterned hard mask stack on the conductive layer, wherein the hard mask stack comprises at least a first mask layer;
dry etching the patterned hard mask stack and the conductive layer to provide a structured hard mask stack and to expose portions of the functional semiconductor layer stack;
depositing a first protective layer at least on a sidewall of the conductive layer, the first protective layer comprising similar etching properties as the first mask layer and being resilient to a wet chemical etching process;
first anisotropic dry chemical etching portions of the structured hard mask stack and the functional semiconductor layer stack not covered by the structured hard mask stack to a first depth exposing edges of the active region;
performing the wet chemical etching process, wherein side edges of the conductive layer are protected by the first protective layer;
covering the exposed edges of the active region with a second protective layer;
second anisotropic dry chemical etching further portions of the structured hard mask stack and the functional semiconductor layer stack not covered by the structured hard mask to a second depth;
removing the second protective layer; and
further processing the optoelectronic device such that a portion of the first mask layer and the second protective layer remain on the functional semiconductor layer stack and on the sidewall of the conductive layer, respectively.

26. The method according to claim 25, wherein providing the functional semiconductor layer stack comprises:
depositing a functional semiconductor layer stack;
depositing a conductive material on the surface of the functional semiconductor layer stack;
optional depositing an annealing layer on top of the conductive material; and
depositing the conductive layer on the conductive material after removing the annealing layer on the conductive material, the conductive layer being more compatible with a dry etching process used to structure the patterned hard mask or more resilient against KOH.

27. The method according to claim 25, wherein depositing the patterned hard mask stack comprises:
depositing the first mask layer of SiNx on the conductive layer having a thickness in a range of larger than 500 nm;
optional depositing a second layer comprising SiO2 on the first mask layer, the second layer having a smaller thickness than the first mask layer; and
depositing a photoresist and pattern the photoresist.

28. The method according to claim 25, wherein the first protective layer comprises the same material as the first mask layer having a thickness on the sidewall in a range of 10 nm to 70 nm.

29. The method according to claim 28, wherein the first protective layer encapsulates the first mask layer of the structured hard mask stack and at least partially covers the exposed portions of the functional semiconductor layer stack.

30. The method according to claim 25, wherein first anisotropic dry chemical etching causes inclined sidewalls in the functional semiconductor layer stack.

31. The method according to claim 25, wherein the first depth is in a range between 300 nm and 1000 nm.

32. The method according to claim 25, wherein the wet chemical etching process comprises etching with KOH.

33. The method according to claim 25, wherein covering the exposed edges of the active region comprises depositing the second protective layer onto sidewalls using an ALD process having a thickness in a range smaller than 60 nm.

34. The method according to claim 25, wherein second anisotropic dry chemical etching comprises the same etchant as the first anisotropic dry chemical etching, and/or wherein the second anisotropic dry chemical etching removes the second protective layer on top of the functional semiconductor layer stack.

35. The method according to claim 25, wherein second anisotropic dry chemical etching causes inclined surface portions of the functional semiconductor layer stack.

36. The method according to claim 25, wherein second anisotropic dry chemical etching is performed until an undoped buffer layer of the functional semiconductor layer stack is reached, and/or wherein second anisotropic dry chemical etching removes portions of the first mask layer.

37. The method according to claim 25, wherein the functional semiconductor layer stack comprises a semiconductor material from the group consisting of GaN, InGaN and InAlGaN, and wherein optionally a crystal orientation of the semiconductor material is substantially inert to the wet chemical etching process.

38. The method according to claim 25, wherein further processing the optoelectronic device comprises:
depositing a third protective layer using an ALD process on sidewalls and the surface encapsulating remaining portions of the first mask layer, the conductive layer and the active region of the functional semiconductor layer stack;
structuring the third protective layer and the remaining portion of the first mask layer to expose a portion of the conductive layer; and
depositing a metal layer on the third protective layer, electrically connecting the conductive layer.

39. The method according to claim 25, wherein further processing the optoelectronic device comprises:
encapsulating the optoelectronic device within a sacrificial layer;
encapsulating the optoelectronic device with a filling material;
forming an anchor by the filling material supporting the optoelectronic device, the anchor extending through the sacrificial layer; and
removing the sacrificial layer.

40. An optoelectronic device comprising:
a functional layer stack comprising:
a first doped layer;
a second doped layer;
an active region located between the first doped layer and the second doped layer;
a conductive layer located on a surface of the second doped layer;
a structured non-conductive mask layer located on the conductive layer;
a structured protective layer located on the non-conductive mask layer; and
a metal layer located on the structured protective layer electrically connecting the conductive layer,
wherein the structured protective layer extends on sidewalls of the structured non-conductive mask layer, of the conductive layer and of the active region, and
wherein a sidewall of the non-conductive mask layer is substantially flush with a sidewall of the conductive layer.

41. The optoelectronic device according to claim 40, wherein a sidewall of the active region is flush with the sidewall of the conductive layer.

42. The optoelectronic device according to claim 40, wherein a second sidewall is laterally displaced to a sidewall of the active region and extends along a portion of the first doped layer.

43. The optoelectronic device according to claim 42, wherein an angle between the sidewall of the active region and the second sidewall is larger than 0°.

44. The optoelectronic device according to claim 40, further comprising a material layer located between the sidewall of the conductive layer and the structured protective layer, wherein the material layer comprises the same material as the structured non-conductive mask layer.

45. The optoelectronic device according to claim 44, wherein the conductive layer comprises a first metal layer and a transparent conductive oxide.

46. The optoelectronic device according to claim 44, wherein the metal layer is positioned only on a top surface of the structured protective layer.

47. The optoelectronic device according to claim 44, wherein the structured protective layer comprises Al2O3.

48. The optoelectronic device according to claim 40, wherein a material of the structured non-conductive mask layer comprises SiNx.
